(19) United States
(12) Patent Application Publication
(10) Pub. No.: US 2007/0075423 A1
(43) Pub. Date: Apr. 5, 2007

(54) Semiconductor element with conductive bumps and fabrication method thereof

(75) Inventors: Chun-Chi Ke, Taichung (TW); Kook-Jui Tai, Taichung (TW); Chien-Ping Huang, Taichung (TW)

Correspondence Address: ISHIMARU & ZAHRT LLP, 333 W. EL CAMINO REAL, SUITE 330, SUNNYVALE, CA, 94087, US

(73) Assignee: Siliconware Precision Industries Co., Ltd., Taichung (TW)

(21) Appl. No.: 11/295,885

(22) Filed: Dec. 6, 2005

(30) Foreign Application Priority Data
Sep. 30, 2005 (TW) 94134147

(51) Int. Cl. H01L 23/48; H01L 29/40

(52) U.S. Cl. 257/737; 438/614; 438/108; 257/750; 257/778

(57) ABSTRACT

A semiconductor element with conductive bumps and a fabrication method thereof are provided. The fabrication method includes providing a semiconductor element having a plurality of bond pads formed on an active surface thereof, wherein each of the bond pads has a predetermined bonding area; applying a passivation layer on the active surface, with a plurality of openings formed for exposing the predetermined bonding areas; applying a buffer layer on the passivation layer to cover the predetermined bonding areas; allowing the buffer layer with a plurality of openings to be formed for exposing a portion of the predetermined bonding areas; forming a under bump metallurgy (UBM) layer on the bond pads, allowing the predetermined bonding areas to be completely covered by the UBM layer; and implanting conductive bumps on the UBM layer. The buffer layer advantageously absorbs stresses exerted to the conductive bumps, thereby preventing the conducting bumps from cracking.

### FIELD OF THE INVENTION

The present invention relates to a semiconductor element with conductive bumps and a fabrication method thereof. More particularly, the present invention relates to a semiconductor element with conductive bumps applied to Flip Chip technology and a fabrication method thereof.

### BACKGROUND OF THE INVENTION

With the progress of semiconductor process technology and the improvement of electrical performance on chips, along with increasing demands for various portable products in the fields of communications, networks and computers, semiconductor packaging technology that can reduce the size of integrated circuits and have higher pin counts such as Ball Grid Array (BGA), Flip Chip and Chip Size Package (CSP), is becoming the mainstream.

As to the flip chip semiconductor package, a plurality of conducting bumps are implanted on a plurality of bump pads formed on a semiconductor substrate such as a wafer or a chip, and the conductive bumps are electrically connected to a carrier such as a substrate directly. Compared to the wire bonding method, the flip chip semiconductor package is shorter in circuit paths and better in electrical performance. Meanwhile, the flip chip semiconductor package can have enhanced heat dissipation when the back side of the chip of the semiconductor package is exposed.

As disclosed in U.S. Pat. Nos. 6,111,321, 6,229,220, 6,107,180 and 6,586,323, an Under Bump Metallurgy (UBM) layer 14 should be formed before forming a conductive bump 17 on a semiconductor substrate 10 when the flip chip semiconductor technology is applied, in order to bond the conductive bump 17 tightly to the semiconductor substrate 10 as shown in FIG. 1 (PRIOR ART). However, when the conductive bump 17 is electrically connected to a substrate directly, the stress resulted from CTE (coefficient of thermal expansion) mismatch between the semiconductor substrate 10 and the substrate tends to impose on the conductive bump 17 and the UBM layer 14, thus causing the conductive bump 17 to crack and delaminate from the UBM layer 14. As a result, the electrical performance and reliability of the semiconductor package are adversely affected.

To eliminate the aforementioned problems, as described in U.S. Pat. Nos. 5,720,100, 6,074,895 and 6,372,544, an underfill is utilized to fill the space between the semiconductor substrate such as a chip and the substrate for the sake of alleviating the stress exerted to the conductive bumps and UBMs. However, underfilling alone is not satisfactory in eliminating the aforementioned problems and is time consuming to carry out.

Another approach for solving the cracking and delamination problems is Re-Passivation, which is a method that forming on a passivation layer of a semiconductor substrate a buffer layer such as benzo-cyclo-butene or polyimide before forming the UBM. By the buffer layer, the thermal stress exerted to the conductive bumps and UBMs can be reduced. The formation of the buffer layer is illustrated by FIG. 2A to 2E (PRIOR ART).

First, as shown in FIG. 2A (PRIOR ART), a semiconductor substrate 10 having a plurality of bond pads (I/O connections) 11 is covered by a passivation layer 12 with a plurality of openings formed thereon for exposing a portion of each of bond pads 11 on the semiconductor substrate 10. For the purpose of simplifying illustration, merely a bond pad 11 on the semiconductor substrate 10 is depicted in each of the drawings. Next, as shown in FIG. 2B (PRIOR ART), a buffer layer 13 such as polyimide, is formed over the passivation layer 12 with a plurality of openings to expose the bond pads 11. Then, as shown in FIG. 2C (PRIOR ART), a UBM layer 14 is formed on the bond pad 11 by sputtering or plating technique. After that, as shown in FIG. 2D (PRIOR ART), a dry film 15 is coated to cover the buffer layer 13, leaving the UBM layer 14 to be exposed in order for solder 16 to coat on the exposed UBM layer 14. Finally, after in turn performing a first reflow to the solder 16, removing the dry film 15 and performing a second reflow to the solder 16, a conductive bump 17 is obtained as shown in FIG. 2E (PRIOR ART).

Problems of cracking and delamination as described above can be reduced when the line width between circuits formed in the semiconductor substrate is less than 0.13 μm. This is because the buffer layer 13 formed between the UBM layer 14 and the passivation layer 12 is capable of absorbing the thermal stress exerted to the UBM layer 14 and the conductive bump 17. However, when the line width is less than 90 nm or even reduced to 65 nm, 45 nm or 32 nm, to overcome the resistance/capacity time delay induced by the reduction of line width, dielectric material with low dielectric constant (low k) should be used as the buffer lay 13. By the use of the dielectric material with low dielectric constant, the metal circuits formed in the semiconductor substrate can be closely arranged and signal leakage and interference can be prevented and the transmission speed can also be relatively enhanced. Nevertheless, with the low k feature, the dielectric material is hard and crisp in nature such that delamination of the buffer layer 13 tends to occur and adversely affect the electrical performance. It is mainly because the thermal stress still primarily exerts to the interface between the conductive bump 17 and the UBM layer 14, whereas the buffer layer 13 formed under the UBM layer 14 can only receive a portion of the thermal stress in a lateral direction. As a result, delamination of the buffer layer 13 may still occur, as the buffer layer 13 fails to provide sufficient buffer effect to offset the thermal stress.

Accordingly, U.S. Pat. No. 5,431,328 discloses a method to solve the above mentioned problems. As shown in FIG. 3 (PRIOR ART), a polymer bump 20, constituted by elastic polymer, is formed on each of the bond pads 11 of the semiconductor substrate 10. Then, the polymer bump 20 is covered with a metal coating 21. A soldering coating 22 is further formed over the metal coating 21 for the purpose of replacing the conventional conducting bump and acting as an electrical connector. By the elasticity of the polymer bump 20, the stress resulted form the process can be absorbed. However, the process for such a bump structure is complicated and the production cost is high, thus not meeting the demand for mass production.

It is desired to develop an improved semiconductor element with conductive bumps and a fabrication method thereof, which can eliminate the problems due to stress and can lower production cost.

### SUMMARY OF THE INVENTION

To overcome the aforementioned and other problems, it is an objective of the present invention to provide a semiconductor element with conductive bumps and a fabrication method thereof that has lower stress.

It is another objective of the present invention to provide a semiconductor element with conductive bumps and a fabrication method thereof that allow lower production cost.

It is a further objective of the present invention to provide a semiconductor element with conductive bumps and a fabrication method thereof for effectively preventing the conductive bumps from cracking.

It is still another objective of the present invention to provide a semiconductor element with conductive bumps and a fabrication method thereof that are simple to proceed.

It is still another objective of the present invention to provide a semiconductor element with conductive bumps and a fabrication method thereof without the need of an additional coating process.

It is still another objective of the present invention to provide a semiconductor element with conductive bumps and a fabrication method thereof for preventing dielectric layer from lamination.

To achieve the aforementioned and other objectives, a semiconductor element with conductive bumps is provided according to a preferred embodiment of the present invention, which comprises: a semiconductor element having a plurality of bond pads formed on an active surface of the semiconductor element, wherein each of the bond pads has a predetermined bonding area; a passivation layer applied on the active surface with a plurality of openings formed for exposing the predetermined bonding areas; a buffer layer applied on the passivation layer and having a plurality of openings for exposing a portion of the predetermined bonding areas; a under bump metallurgy (UBM) layer formed on the plurality of bond pads for completely covering the predetermined bonding area; and a plurality of conductive bumps implanted on the UBM layer.

The fabrication method of the semiconductor element with conductive bumps comprises the steps of: providing a semiconductor element having a plurality of bond pads formed on an active surface of the semiconductor element, wherein each of the bond pads has a predetermined bonding area; applying a passivation layer on the active surface with a plurality of openings formed for exposing the predetermined bonding areas; applying a buffer layer on the passivation layer to cover the predetermined bonding areas; allowing the buffer layer with a plurality of openings to be formed for exposing a portion of the predetermined bonding areas; forming a UBM layer on the bond pads, allowing the predetermined bonding areas to be completely covered by the UBM layer; and implanting conductive bumps on the UBM layer.

The fabrication method of the semiconductor element with conductive bumps according to the second preferred embodiment of the present invention comprises the steps of: providing a semiconductor element having a plurality of bond pads formed on an active surface of the semiconductor element, wherein each of the bond pads has a predetermined bonding area; applying a passivation layer on the active surface with a plurality of openings formed for exposing the predetermined bonding areas; applying a buffer layer on the passivation layer to partly cover the predetermined bonding areas; forming a UBM layer on the bond pads, allowing the predetermined bonding areas to be completely covered by the UBM layer; and implanting conductive bumps on the UBM layer.

The features of the present invention are that allowing a portion of the buffer layer on the predetermined bonding areas of the bond pads to be remained by etching or masking and the buffer layer on the predetermined bonding areas may be jointed to edges of the plurality of openings of the buffer layer or may not be jointed to edges of the plurality of openings of the buffer layer, wherein the buffer layer on the predetermined bonding areas has a shape of roundness, strip or cross; and the buffer layer on the predetermined bonding areas is completely covered by the UBM layer.

Furthermore, the semiconductor element may be a wafer and the passivation layer may be made of silicon nitride and the buffer layer may be a polymer layer such as polyimide. The plurality of openings of the passivation layer may be formed by exposing, developing and etching.

Therefore, according to the present invent, a portion of the buffer layer would be remained on the predetermined bonding areas of the bond pads and the predetermined bonding areas do not directly and completely contact with the UBM layer and the conductive bumps. Compared to conventional technology, the stress exerted on the conductive bumps can be sufficiently absorbed by the buffer layer with low elasticity modulus in the present invention and the present invention also has the advantages of low fabrication cost and simple preparing process which does not require additional preparing steps not used by conventional technology.

The following illustrative embodiments are provided to illustrate the disclosure of the present invention, these and other advantages and effects can be apparently understood by those skilled in the art after reading this specification. The present invention can also be performed or applied by other different embodiments. The details of the specification may be modified and varied on the basis of different points and applications without departing from the spirit of the present invention.

### BRIEF DESCRIPTION OF THE DRAWINGS

FIG. 1 (PRIOR ART) is a cross-sectional view of a conventional semiconductor element with conducting bumps.

FIGS. 2A to 2E (PRIOR ART) are cross-sectional views of another conventional process for fabricating a semiconductor element with conducting bumps.

FIG. 3 (PRIOR ART) is a cross-sectional view of a semiconductor element with conducting bumps disclosed in U.S. Pat. No. 5,431,328.

FIG. 4A to 4F are cross-sectional views of the process for fabricating a semiconductor element with conducting bumps according to the present invention.

FIG. 5 is a cross-sectional view of a preferred semiconductor element with conducting bumps according to the present invention.

FIG. 6 is a cross-sectional view of another semiconductor element with conducting bumps according to the present invention.

FIG. 7 is a top view of still another semiconductor element with conducting bumps according to the present invention.

FIG. 8 is a top view of still another semiconductor element with conducting bumps according to the present invention.

FIG. 9 is a cross-sectional view of still another semiconductor element with conducting bumps according to the present invention.

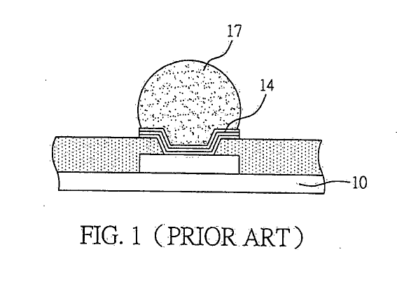

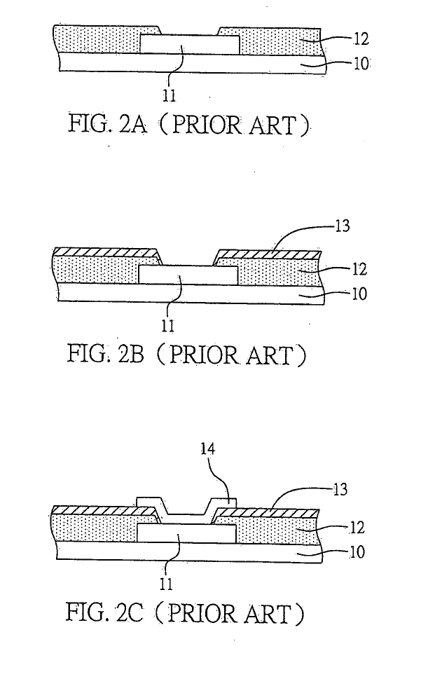

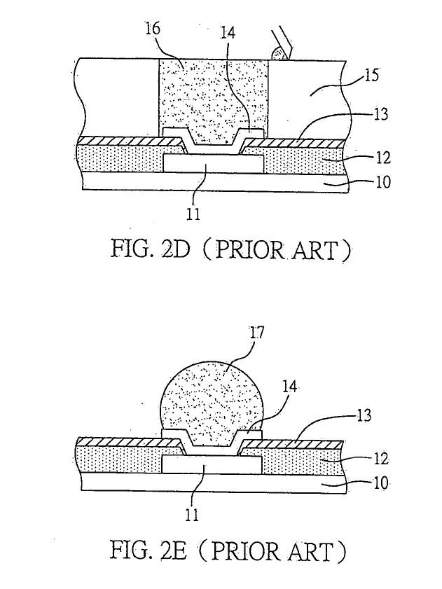

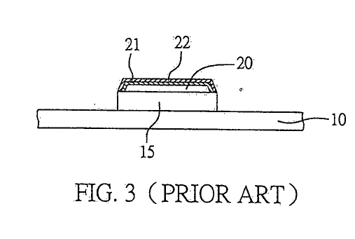

### DETAILED DESCRIPTION OF THE PREFERRED EMBODIMENTS

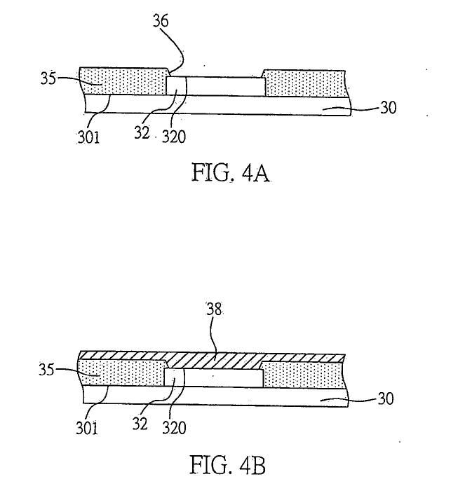

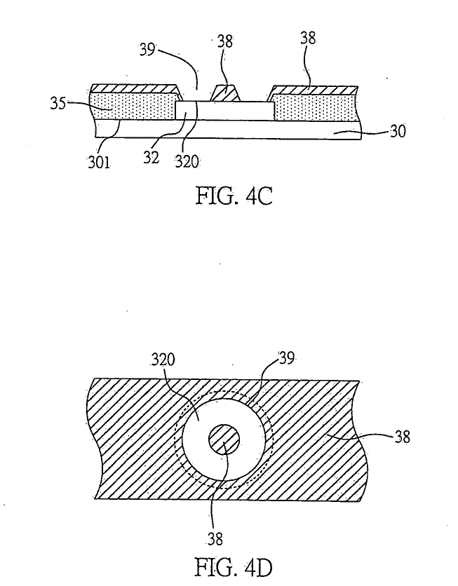

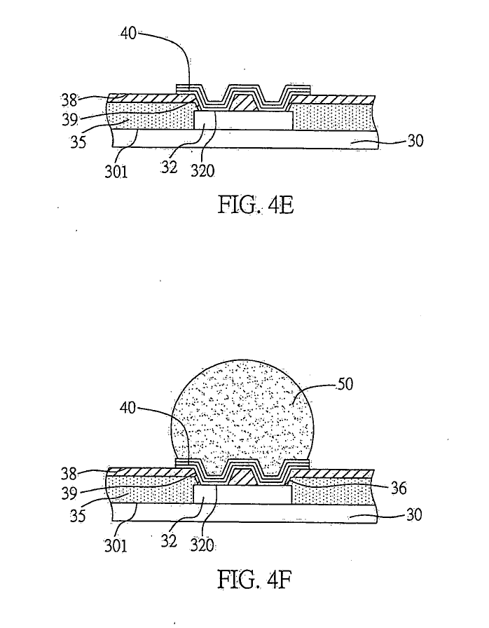

A preferred embodiment of a semiconductor element with conductive bumps according to the present invention is shown by FIGS. 4A to 4F. First, as shown in FIG. 4A, a semiconductor element such as a wafer 30 is provided, having a plurality of bond pads 32 for electrical transmission formed on an active surface 301 of the wafer 30. Each of the bond pads 32 has a round predetermined bonding area 320. A passivation layer 35, made of silicon nitride or polyimide, is applied on the active surface 301 and the passivation layer 35 has a plurality of openings 36 for exposing the predetermined bonding area 320 of each of the bond pads 32.

Secondly, as shown in FIG. 4B, a buffer layer 38, made of low elasticity modulus material such as polyimide or other polymer, is formed on the passivation layer 35 to cover the passivation layer 35 and exposed area of the predetermined bonding area 320 from the passivatin layer 35.

Thirdly, as shown in FIG. 4C, which is the feature of the present invention, a plurality of openings 39 are formed in the passivation layer 38 by exposing, developing and etching, thereby to partially expose the predetermined bonding areas 320 of the bond pads 32. During this process, the buffer layer 38 over the predetermined bonding areas 320 of the bonding pads 32 is not completely etched by a predetermined design, that is, a portion of the buffer layer 38 still is remained on the predetermined bonding area 320. In this embodiment, the buffer layer 38 remained on the predetermined bonding area 320 has a shape of roundness. As shown in FIG. 4D, only a circular region of the buffer layer 38 on the predetermined bonding area 320 is etched, thereby to expose a circular predetermined bonding area 320 of the bonding pad 32.

Then, as shown in FIG. 4E, a UBM layer 40 is formed on the plurality of bond pads 32 to completely cover the predetermined bonding areas 320 of the bond pads 32. During this process, the round buffer layer 38 over the predetermined bonding areas 320 is covered completely by the UBM layer 40.

Finally, as shown in FIG. 4F, a plurality of conductive bumps 50 are implanted on the UBM layer 40, thus electrical connection between the plurality of conductive bumps 50 and the predetermined bonding areas 320 of the bond pads 32 achieved.

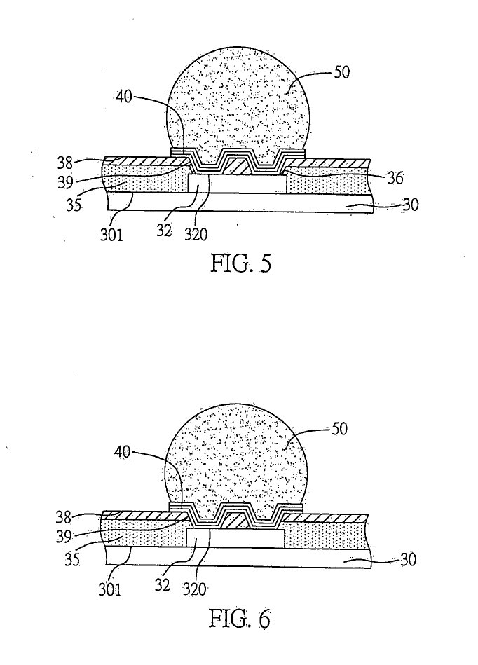

Therefore, the semiconductor element with conductive bumps 50 referring to the preferred embodiment of the present invention is as shown in the FIG. 5, comprising a semiconductor element such as a wafer 30 with a plurality of bond pads 32 formed on an active surface 301 of the wafer 30,wherein each of the bond pads 32 has a round predetermined bonding area 320; a passivation layer 35 such as silicon nitride or polyimide applied on the active surface 301 of the wafer 30 and a plurality of openings 36 formed in the passivation layer 35 to expose the predetermined bonding area 320 of each of the bond pads 32; a buffer layer 38 such as polyimide applied on the passivation layer 35 and a plurality of openings 39 formed in the buffer layer 38 to expose the predetermined bonding area 320 of the bond pad 32, thus a portion of the buffer layer 38 still remained on the predetermined bonding area 320; a UBM layer 40 formed on the plurality of bond pads 32 to completely cover the predetermined bonding areas 320 of the bond pads 32; and a plurality of conductive bumps 50 formed on the UBM layer 40.

Therefore, based on the present invention, a portion of the buffer layer 38 would be remained on the predetermined bonding areas 320 of the bond pads 32 and the predetermined bonding areas 320 do not directly and completely contact with the UBM layer 40 and the conductive bumps 50. Compared to conventional technology, the stress exerted on the conductive bumps 50 can be sufficiently absorbed by the buffer layer material with low elasticity modulus in the present invention, thus preventing the UBM layer 40 and the buffer layer 38 from lamination and preventing the conductive bumps 50 from cracking, meanwhile, the present invention also has the advantages of low fabrication cost and simple manufacturing process which merely changes the photo-lithographic process and does not need additional processing steps not used by conventional technology.

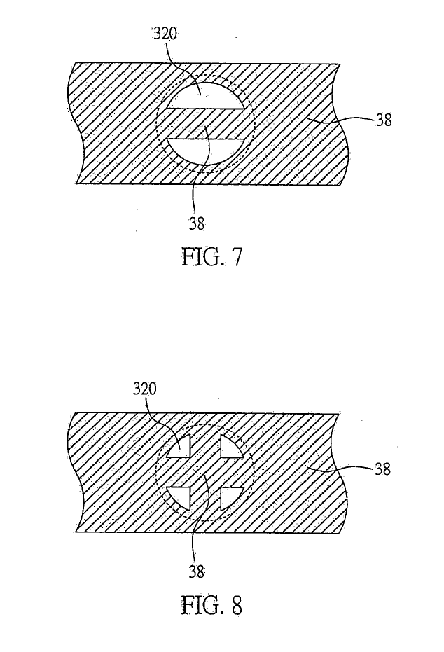

In addition to the above mentioned embodiments, the structure of the semiconductor element of the present invention can also be modified. For example, after forming a plurality of openings 39 in the buffer layer 38, edges of the openings 36 of the passivation layer 35 may be covered by the buffer layer 38 as shown in FIG. 5, or edges of the openings 36 of the passivation layer 35 may be not covered by the buffer layer 38 as shown in FIG. 6.

Furthermore, in the above mentioned embodiments, the buffer layer 38 applied on the predetermined bonding area 320 has a shape of roundness, that is, the buffer layer 38 on the predetermined bonding area 320 is not jointed to edges of the openings 39 of the buffer layer 38. But it is not limited to this structure. In the present invention, the buffer layer 38 applied on the predetermined bonding area 320 may also be jointed to edges of the opening 39 of the buffer layer 38 such that the buffer layer 38 on the predetermined bonding area 320 is continuous. For example, the buffer layer 38 on the predetermined bonding area 320 may be a strip as shown in FIG. 7, or may be a cross as shown in the FIG. 8. These all are embodiments of the present invention and their buffer layer 38 all can absorb the stress applied to the conductive bumps.

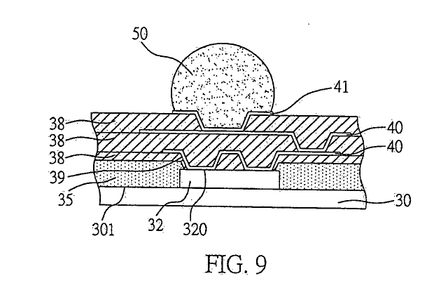

Moreover, the semiconductor element of the present invention may also be a multi-level structure as shown in FIG. 9. At least one buffer layer 38 and UBM layer 40 may further be formed on the first UBM layer 40, and finally a plurality of conductive bumps 50 are formed on the topmost UBM layer 41.

The foregoing descriptions of the detailed embodiments are only to disclose the features and functions of the present invention and do not intend to limit the scope of the present invention. It should be understood to those in the art that all modifications and variations according to the spirit and principle of the present invention should fall within the scope of the appended claims.

What is claimed is:

1. A semiconductor element with conductive bumps, comprising:
the semiconductor element having a plurality of bond pads formed on an active surface of the semiconductor element, wherein each of the bond pads has a predetermined bonding area;
a passivation layer applied on the active surface of the semiconductor element, with a plurality of openings being formed in the passivation layer for exposing the predetermined bonding areas;
a buffer layer applied on the passivation layer and having a plurality of openings for exposing a portion of the predetermined bonding areas;
an under bump metallurgy (UBM) layer formed on the plurality of bond pads, for completely covering the predetermined bonding areas; and
a plurality of the conductive bumps implanted on the UBM layer.

2. The semiconductor element with conductive bumps of claim 1, wherein a portion of the buffer layer remains on the predetermined bonding areas of the bond pads.

3. The semiconductor element with conductive bumps of claim 2, wherein the buffer layer on the predetermined bonding areas is free of being connected to edges of the plurality of openings of the buffer layer.

4. The semiconductor element with conductive bumps of claim 2, wherein the buffer layer on the predetermined bonding areas is connected to edges of the plurality of openings of the buffer layer.

5. The semiconductor element with conductive bumps of claim 2, wherein the buffer layer on the predetermined bonding areas has a shape of one of roundness, strip and cross.

6. The semiconductor element with conductive bumps of claim 2, wherein the buffer layer on the predetermined bonding areas is completely covered by the at least one UBM layer.

7. The semiconductor element with conductive bumps of claim 1, further comprising at least one buffer layer and at least one UBM layer, which are located between the UBM layer and the plurality of conductive bumps.

8. The semiconductor element with conductive bumps of claim 1, wherein edges of the plurality of openings of the passivation layer are covered by the buffer layer.

9. The semiconductor element with conductive bumps of claim 1, wherein edges of the plurality of openings of the passivation layer are free of being covered by the buffer layer.

10. The semiconductor element with conductive bumps of claim 1, wherein the semiconductor element is a wafer.

11. The semiconductor element with conductive bumps of claim 1, wherein the predetermined bonding area of the bond pad has a shape of roundness.

12. The semiconductor element with conductive bumps of claim 1, wherein the passivation layer is one of a silicon nitride layer and a polyimide layer.

13. The semiconductor element with conductive bumps of claim 1, wherein the buffer layer is made of polyimide.

14. The semiconductor element with conductive bumps of claim 1, wherein the buffer layer is made of low elasticity modulus material.

15. The semiconductor element with conductive bumps of claim 1, wherein the plurality of openings of the buffer layer are formed by exposing, developing and etching.

16. A fabrication method of a semiconductor element with conductive bumps, comprising the steps of:
providing the semiconductor element having a plurality of bond pads formed on an active surface of the semiconductor element, wherein each of the bond pads has a predetermined bonding area;
applying a passivation layer on the active surface of the semiconductor element, with a plurality of openings being formed in the passivation layer for exposing the predetermined bonding areas;
applying a buffer layer on the passivation layer to cover the predetermined bonding areas;
forming a plurality of openings in the buffer layer to expose a portion of the predetermined bonding areas;
forming an under bump metallurgy (UBM) layer on the bond pads, allowing the predetermined bonding areas to be completely covered by the UBM layer; and
implanting the conductive bumps on the UBM layer.

17. The fabrication method of claim 16, wherein a portion of the buffer layer remains on the predetermined bonding areas of the bond pads after the plurality of openings of the buffer layer being formed.

18. The fabrication method of claim 17, wherein the buffer layer on the predetermined bonding areas is free of being connected to edges of the plurality of openings of the buffer layer.

19. The fabrication method of claim 17, wherein the buffer layer on the predetermined bonding areas is connected to edges of the plurality of openings of the buffer layer.

20. The fabrication method of claim 17, wherein the buffer layer on the predetermined bonding areas has a shape of one of roundness, strip and cross.

21. The fabrication method of claim 17, wherein the buffer layer on the predetermined bonding areas is completely covered by the UBM layer.

22. The fabrication method of claim 16, further comprising forming at least one buffer layer and at least one UBM layer before the conductive bumps being implanted on the UBM layer.

23. The fabrication method of claim 16, wherein edges of the plurality of openings of the passivation layer are covered by the buffer layer.

24. The fabrication method of claim 16, wherein edges of the plurality of openings of the passivation layer are free of being covered by the buffer layer.

25. The fabrication method of claim 16, wherein the semiconductor element is a wafer.

26. The fabrication method of claim 16, wherein the predetermined bonding area of the bond pad has a shape of roundness.

27. The fabrication method of claim 16, wherein the passivation layer is one of a silicon nitride layer and a polyimide layer.

28. The fabrication method of claim 16, wherein the buffer layer is made of polyimide.

29. The fabrication method of claim 16, wherein the buffer layer is made of low elasticity modulus material.

30. The fabrication method of claim 16, wherein the plurality of openings of the buffer layer are formed by exposing, developing and etching.
